(19) United States
(12) Patent Application Publication
(10) Pub. No.: US 2010/0132770 A1
(43) Pub. Date: Jun. 3, 2010

(54) Device including semiconductor nanocrystals and a layer including a doped organic material and methods

(76) Inventors: Paul H.J. Beatty, Placerville, CA (US); Seth Coe-Sullivan, Belmont, MA (US)

Correspondence Address: QD VISION, INC., 313 PLEASANT STREET, 4TH FLOOR, WATERTOWN, MA, 02472, US

(21) Appl. No.: 11/704,145

(22) Filed: Feb. 8, 2007

Related U.S. Application Data
(60) Provisional application No. 60/795,420, filed on Apr. 27, 2006.
(60) Provisional application No. 60/771,643, filed on Feb. 9, 2006.

(51) Int. Cl. H01L 31/04; H01L 29/66; H01L 51/40; H01L 51/52; H01L 51/44

(52) U.S. Cl. 136/252; 257/15; 438/99; 257/13; 257/21; 257/E29.168; 257/E21.04; 257/E51.018; 257/E51.012; 977/774

(57) ABSTRACT

A device including semiconductor nanocrystals and a layer comprising a doped organic material disposed over the substrate and in electrical connection with at least one semiconductor nanocrystals is disclosed. Methods for making the device and for improving the efficiency of a device are also disclosed.

### TECHNICAL FIELD OF THE INVENTION

The present invention relates to a device including semiconductor nanocrystals, and more particularly, to a device including semiconductor nanocrystals and an organic layer.

### SUMMARY OF THE INVENTION

It has been recognized that it would be advantageous to develop an improved device including semiconductor nanocrystals and improved methods for making a device including semiconductor nanocrystals.

In accordance with one aspect of the present invention, there is provided a device including semiconductor nanocrystals and a layer comprising a doped organic material. In certain embodiments, the layer is in electrical connection with at least one semiconductor nanocrystal. In one detailed aspect, the doped organic material comprises a material that can transport electrons. In another detailed aspect, the doped organic material comprises a material that can transport holes. In another detailed aspect, the doped organic material comprises a material that can inject holes. In another detailed aspect, the doped organic material comprises a material that can inject electrons. In another detailed aspect, the doped organic material comprises a material that can block holes. In another detailed aspect, the doped organic material comprises a material that blocks electrons. In other detailed aspects, more than one layer comprising a doped organic material is included in the device.

In accordance with another aspect of the invention, there is provided a method for making a device including semiconductor nanocrystals comprising including a layer comprising a doped organic material in electrical connection with at least one semiconductor nanocrystal. In one detailed aspect, the doped organic material comprises a material that can transport electrons. In another detailed aspect, the doped organic material comprises a material that can transport holes. In another detailed aspect, the doped organic material comprises a material that can inject holes. In another detailed aspect, the doped organic material comprises a material that can inject electrons. In another detailed aspect, the doped organic material comprises a material that can block holes. In another detailed aspect, the doped organic material comprises a material that blocks electrons. In other detailed aspects, more than one layer comprising a doped organic material is included in the device.

In accordance with another aspect of the invention, there is provided a method for improving the efficiency of a device including semiconductor nanocrystals comprising including a layer comprising a doped organic material in electrical connection with at least one semiconductor nanocrystal. In one detailed aspect, the doped organic material comprises a material that can transport electrons. In another detailed aspect, the doped organic material comprises a material that can transport holes. In another detailed aspect, the doped organic material comprises a material that can inject holes. In another detailed aspect, the doped organic material comprises a material that can inject electrons. In another detailed aspect, the doped organic material comprises a material that can block holes. In another detailed aspect, the doped organic material comprises a material that blocks electrons. In other detailed aspects, more than one layer comprising a doped organic material is included in the device.

The foregoing, and other aspects described herein all constitute embodiments of the present invention.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings:

FIG. 1 is a schematic drawing depicting a light-emitting device.

The attached FIGURE is a simplified representation presented for purposes of illustration only; the actual structures may differ in numerous respects, including, e.g., relative scale, etc.

For a better understanding to the present invention, together with other advantages and capabilities thereof, reference is made to the following disclosure and appended claims in connection with the above-described drawings.

### DETAILED DESCRIPTION OF THE INVENTION

In accordance with one aspect of the present invention, there is provided a device comprising semiconductor nanocrystals and a layer comprising a doped organic material.

Doping can lead to an increase in the conductivity of a layer, which can reduce resistance losses, and can lead to an improved transition of charge between the electrodes and the organic material.

As used herein, the terms “doping” and “doped” refer to the addition of a second constituent to a base material where the concentration of the second constituent may range from just over zero to almost 100%.

In certain embodiments, a device can include at least one layer separating two electrodes of the device. Semiconductor nanocrystals can also be disposed between the two electrodes. The material of the at least one layer can be chosen based on the material's ability to transport holes, or the hole transport layer (HTL). Alternatively, the material of the at least one layer can be chosen based on the material's ability to transport electrons, or the electron transport layer (ETL). In certain embodiments, the electron transport layer can include the semiconductor nanocrystals. In certain embodiments, the hole transport layer can include the semiconductor nanocrystals. In certain embodiments, the semiconductor nanocrystals can be disposed between the charge transport layer and the electron transport layer. Other materials may also be included between the ETL and HTL. In certain embodiments, the semiconductor nanocrystals can be included in the device as one or more separate layers which can be patterned or unpatterned. When a voltage is applied across the device, one electrode injects holes (positive charge carriers) into the device structure, while the other electrode injects electrons into the device structure. The injected holes and electrons each migrate toward the oppositely charged electrode. When an electron and a hole localize on the same semiconductor nanocrystal, an exciton is formed, which can recombine to emit light (e.g., as in a light-emitting device), or which can be converted into another electrical response (e.g., as in a photodetector, a photovoltaic device, an imaging device, a solar cell, etc.).

It is understood that heretofore, organic materials used in forming the hole transport layers and/or electron transport layers of devices including semiconductor nanocrystals have been intrinsic (undoped) materials. If additional charge (electron and/or hole) injection and/or charge (electron and/or hole) blocking layers formed from organic materials have been further included in a device including semiconductor nanocrystals, such organic materials have similarly been intrinsic (undoped) materials.

Hole transport and/or electron transport layers can be more generally referred to as charge transport layers.

Each charge transport layer included in the device may also optionally include two or more charge transport layers (which may comprise the same or different charge transport material).

It is expected that the efficiency of devices including semiconductor nanocrystals can be enhanced by including a layer including a doped organic material in the device.

In one detailed aspect, the doped organic material comprises a material that can transport electrons. In this aspect, the layer including the doped organic material functions as an electron transport layer.

Including a doped organic material in the electron transport layer can enhance electron conductivity. Such enhanced electron conductivity is expected to improve device efficiency. Such enhanced efficiency is also expected to improve device life.

In certain embodiments, the electron transport layer comprises an n-doped organic material.

In certain embodiments, the electron transport layer comprises an intrinsic organic electron transport material (e.g., a molecular matrix, which can be polymeric or non-polymeric, e.g., a small molecule matrix material, including, but not limited to, a metal complex of 8-hydroryquinoline ((wherein the metal can be aluminum, gallium, indium, zinc or magnesium) such as, for example, aluminum tris(8-hydroxyquinoline) (Alq₃)); metal thioxinoid compounds; oxadiazole metal chelates; triazoles; sexithiophenes derivatives; pyrazine; styrylanthracene derivatives; etc.) that is n-doped. Examples of n-dopants include, but are not limited to, alkali metals (e.g., Li, Cs, etc.) and stable, donor-type organic molecular material, which can lead to an increased electron conductivity in the doped layer, in comparison with a non-doped layer. In certain embodiments, a dopant comprising an organic molecular material can have a high molecular mass, such as, for example, at least 300 amu.

Examples of doped organic materials for inclusion in an electron transport layer include, but are not limited to, barthophenanthroline (BPhen) doped with Li.

Aluminum(III)bis(2-methyl-8-quinolinato)4-phenylphenolate (BAlq) and 2,9-dimethyl-4,7-diphenyl-1,10-phenanthroline (BCP) can be suitable substitutes for BPhen.

It is believed that doped organic materials useful as electron transport layers in organic light emitting devices (OLEDs) can be used in devices including emissive materials comprising inorganic semiconductor nanocrystals to increase electron conductivity and enhance device efficiency. A non-limiting list of examples of such doped organic materials are disclosed in U.S. Pat. No. 6,982,179 of Wong et al, for “Structure And Method Of Fabricating Organic Devices, issued 3 Jan. 2006 (e.g., BPhen doped with Li, e.g., at a molar ratio of 1:1, etc.); U.S. Published Patent Application No. 2006/0079004 of Werner et al., for Method For Electrical Doping A Semiconductor Material With Cesium”, published 13 Apr. 2006 (BPhen doped with cesium, etc.). The disclosures of the foregoing listed patents are published patent applications are hereby incorporated herein by reference in their entireties.

In another detailed aspect, the doped organic material comprises a material that can transport holes. In this aspect, the layer including the doped organic material functions as a hole transport layer.

Including a doped organic material in the hole transport layer can enhance hole conductivity. Such enhanced hole conductivity is expected to improve device efficiency by avoiding series resistance losses that can be experienced with intrinsic (undoped) hole transport layers, thus enhancing device efficiency. Such enhanced efficiency is also expected to improve device life.

In certain embodiments, the hole transport layer comprises a p-doped organic material.

Examples of doped organic materials for inclusion in a hole transport layer include, but are not limited to, an evaporated HTL comprising, e.g., 4,4′,4″-tris(diphenylamino)triphenylamine (TDATA) that is doped with tetrafluoro-tetracyano-quinodimethane (F₄-TCNQ); p-doped phthalocyanine (e.g., zinc-phthalocyanine (ZnPc) doped with F₄-TCNQ (at, for instance, a molar doping ratio of approximately 1:30); N,N′-diphenyl-N,N′-bis(1-naphthyl)-1,1′biphenyl-4,4″diamine (alpha-NPD) doped with F₄-TCNQ. See J. Blochwitz, et al., “Interface Electronic Structure Of Organic Semiconductors With Controlled Doping Levels”, Organic Electronics 2 (2001) 97-104; R. Schmechel, 48, Internationales Wissenschaftliches Kolloquium, Technische Universtaat Ilmenau, 22-25 Sep. 2003; C. Chan et al., “Contact Potential Difference Measurements Of Doped Organic Molecular Thin Films”, J. Vac. Sci. Technol. A 22(4), July/August 2004. The disclosures of the foregoing papers are hereby incorporated herein by reference in their entireties.

In certain embodiments, the hole transport layer comprises an intrinsic organic hole transport material (for example, an organic chromophore, such as a phenyl amine, such as, for example, N,N′-diphenyl-N,N′-bis(3-methylphenyl)-(1,1′-biphenyl)-4,4′-diamine (TPD), 4-4′-N,N′-dicarbazolyl-biphenyl (CBP), 4,4-bis[N-(1-naphthyl)-N-phenylamino]biphenyl (NPD), etc., a polyaniline, a polypyrrole, a poly(phenylene vinylene), copper phthalocyanine, an aromatic tertiary amine or polynuclear aromatic tertiary amine, a 4,4′-bis(9-carbazolyl)-1,1′-biphenyl compound, or an N,N,N′,N′-tetraarylbenzidine) that is p-doped. Examples of p-dopants include, but are not limited to, stable, acceptor-type organic molecular material, which can lead to an increased hole conductivity in the doped layer, in comparison with a non-doped layer. In certain embodiments, a dopant comprising an organic molecular material can have a high molecular mass, such as, for example, at least 300 amu.

A device of the invention may include a hole-injection layer (either as a separate layer or as part of the hole transport layer) and/or an electron-injection layer (either as a separate layer as part of the electron transport layer).

When included in a device, an injection layer may comprise a doped organic material. For example, a p-doped organic materials useful as hole transport materials can also be included in a hole injection layer of the device. An n-doped organic materials useful as electron transport materials can also be included in an electron injection layer of the device.

Each charge injection layer of the device may optionally include two or more layers (each of which may comprise the same or different material).

In addition to the above-provided examples of doped organic materials that can be included in a charge transport layer and/or charge injection layer of a device including semiconductor nanocrystals, it is believed that doped organic materials useful in charge transport and/or charge-injection layers of organic light emitting devices (OLEDs) can be used in devices including emissive materials comprising inorganic semiconductor nanocrystals to increase charge conductivity and enhance device efficiency. A non-limiting list of examples of such doped organic materials are disclosed in U.S. patent application Ser. No. 10/173,682 to Forrest et al., U.S. Pat. No. 6,982,179 of Wong et al, for “Structure And Method Of Fabricating Organic Devices, issued 3 Jan. 2006 (e.g., 4, 4′,4″-tris(3-methylphenylphenylamino)-triphenylamine (m-MTDATA) doped with F₄-TCNQ, e.g., at a molar ratio of 50:1, etc.) U.S. Published Patent Application No. 2006/0033115 of Blochwitz et al., for “Transparent, Thermally Stable Light-Emitting Component Comprising Organic Layer, published 16 Feb. 2006 (e.g., a hole transport layer doped with a stable, acceptor-type organic molecular material, the molecular mass of the dopant is greater than 200 g/mole, etc.) U.S. Pat. No. 6,565,996 of Hatwar et al., for “Organic Light-Emitting Device Having A Color-Neutral Dopant In A Hole-Transport Layer And/Or In An Electron-Transport Layer”, issued 20 May 2003 (e.g., an HTL including a derivative of anthracene as a color-neutral dopant, etc.), U.S. Published Application No. 2006/049397 of Pfeiffer et al., for Use Of An Organic Matrix Material For Producing An Organic Semiconductor Material, Organic Semiconductor Material And Electronic Component”, published 9 Mar. 2006 (e.g., spiro-TTB doped with F4-TCNQ and Spiro-iPr-TAD doped with F4-TCNQ, U.S. Published Application No. 2005/0242346 of Forrest et al. for Very Low Voltage, High Efficiency pholed In A p-i-n Structure”, published 3 Nov. 2005; U.S. Published Application No. 2003/0230980 of Forrest et al. for Very Low Voltage, High Efficiency Phosphorescent OLED In A p-i-n Structure”, published 18 Dec. 2003; U.S. Published Patent Application No. 2005/0236973 of Leo et al., for “Electroluminescent Assembly”, published 27 Oct. 2005; U.S. Published Patent Application No. 2005/0179399 of Leo et al., for “Pixel For An Active Matrix Display”. Published 18 Aug. 2005 (e.g., examples of p-doped transport layers, etc.); U.S. Published Patent Application No. 2005/0110009 of Blochwitz-Nimoth et al., for “Light-Emitting Component And Process For Its Preparation” published 26 May 2005; U.S. Published Patent Application No. 2004/0062949 of Pfeiffer et al., for “Light Emitting Component Comprising Organic Layers”, published 1 Apr. 2004; U.S. Published Patent Application No. 2004/0251816 of Leo et al., for “Light Emitting Component With Organic Layers”, published 16 Dec. 2004; U.S. Published Patent Application No. 2005/0061232 of Werner et al., for “Doped Organic Semiconductor Materials And Process For Their Preparation”, published 24 Mar. 2005; U.S. Pat. No. 6,980,783 of Kuehl et al., for “Method Of Doping Organic Semiconductors With Quinonediimine Derivatives”, issued 21 Jun. 2005 (e.g., organic mesomeric compounds as organic dopand for doping an organic semiconducting matrix material, etc.); U.S. Published Patent Application No. 2005/0139810 of Kuehl et al., for “Method Of Doping Organic Semiconductors With Quinone Derivatives and 1,3,2-Dioxaborine Derivatives”, published 30 Jun. 2004; U.S. Published Patent Application No. 2005/0121667 of Kuehl et al., for “Method Of Doping Organic Semiconductors With Quinonediimine Derivatives”, published 9 Jun. 2005; U.S. Pat. No. 6,841,270 of Li et al., for “Organic Light-Emitting Device Having Pyrylium Salt as Charge Transport Material”, issued 11 Jan. 2005 (e.g., pyrylium salt or its derivative, as a charge transport material and/or at least a dopant or principal component in a charge transport layer, etc.); U.S. Pat. No. 7,034,174 of Farrand et al., for “Mono-, Oligo-, And Polymers Comprising A 2,6-Azulene Group And Their Use As Charge Transport Materials”, issued 25 Apr. 2006 (e.g., conjugated mono-, oligo- and polyazulenes (doped or undoped) are suitable for use as semiconductors or charge transport materials, etc.); (e.g., mono-, oligo- and polymers comprising at least one 3-(1,1-difluoro-alkyl)thiophene group (oxidatively or reductively doped), etc.); U.S. Pat. No. 6,806,374 of Heeney et al., for “Mono-, Oligo- And Poly-3-(1,1-Difluoroalkyl)Thiophenes And Their Use As Charge Transport Materials”, issued 19 Oct. 2004 (e.g., use of mono-, oligo- and poly-3-(1,1-difluoroalkyl)thiophenes, etc.); U.S. Pat. No. 6,676,857 of Heeney et al., for “Mono-, Oligo- And Poly-4-Fluorothiophenes And Their Use As Charge Transport Materials”, issued 13 Jan. 2004 (e.g., mono-, oligo- and poly-4-fluorothiophenes, (oxidatively or reductively doped or undoped, etc.); U.S. Pat. No. 6,872,475 of Chen et al., for “Binaphthalene Derivatives For Organic Electro-Luminescent Devices”, issued 29 Mar. 2005 (e.g., a binaphthalene derivative is used as the emissive layer and/or one or more of the charge transport layers, or as a host or dopant material for one or more of such layer, etc.). The disclosures of each of the foregoing listed patent and patent publications are hereby incorporated herein by reference in their entireties.

When a charge transport layer including a doped organic material is included in a device, the layer can be thicker in the device than is possible with a layer including undoped material, without causing an increase in the operating voltage. A thicker layer can reduce the likelihood of shorts in the device and can enhance optical cavity optimization.

When both the hole transport layer and electron transport layer include a doped organic material, each of the layers can be thicker in the device than is possible with layers including undoped material, without causing an increase in the operating voltage. Inclusion of a thicker ETL and HTL can further reduce the likelihood of shorts in the device and can further enhance optical cavity optimization.

One or more blocking layers can optionally be further included in the device. For example, an electron blocking layer (EBL), a hole blocking layer (HBL), or an exciton blocking layer (eBL), can be introduced in the structure. A blocking layer can include, for example, 3-(4-biphenyl)-4-phenyl-5-tert butylphenyl-1,2,4-triazole (TAZ), 3,4,5-triphenyl-1,2,4-triazole, 3,5-bis(4-tert-butylphenyl)-4-phenyl-1,2,4-triazole, bathocuproine (BCP), 4,4′,4″-tris{N-(3-methylphenyl)-N phenylamino}triphenylamine (m-MTDATA), polyethylene dioxythiophene (PEDOT), 1,3-bis(5-(4-diphenylamino)phenyl-1,3,4-oxadiazol-2-yl)benzene, 2-(4-biphenyl)-5-(4-tertbutylphenyl)-1,3,4-oxadiazole, 1,3-bis[5-(4-(1,1-dimethylethyl)phenyl)-1,3,4-oxadiazol-5,2-yl)benzene, 1,4-bis(5-(4-diphenylamino)phenyl-1,3,4-oxadiazol-2-yl)benzene, or 1,3,5-tris[5-(4-(1,1-dimethylethyl)phenyl)-1,3,4-oxadiazol-2-yl)benzene.

In accordance with an aspect of the invention, the device including semiconductor nanocrystals includes a layer including a doped organic material that can block holes or electrons. In certain embodiments, a hole blocking layer and an electron blocking layer can be included.

In certain embodiments, the doped organic material comprises an intrinsic blocking materials that is n-doped. Examples of n-dopants include, but are not limited to, alkali metals (e.g., Li, Cs, etc.) and stable, donor-type organic molecular material, which can lead to an increased electron conductivity in the doped layer, in comparison with a non-doped layer. In certain embodiments, a dopant comprising an organic molecular material can have a high molecular mass, such as, for example, at least 300 amu.

Examples of an n-doped blocking layer include lithium doped-bis(2-methyl-8-quinolinolato)-(4-hydroxy-bipheny-1yl)-aluminum (BAlq₃:Li).

Each charge blocking layer of the device may optionally include two or more layers (each of which may comprise the same or different material).

In certain embodiments of the invention that include a doped organic material in at least one charge transport and/or injection layer, it may be preferable to use blocking layers comprising undoped organic material.

In another detailed aspect, two or more layers comprising a doped organic material are included in a device including semiconductor nanocrystals. Inclusion of more than one layer comprising doped organic materials can further improve the efficiency of the device.

In certain embodiments, the charge transport, charge injection, and/or charge blocking layers of the device that do not include doped organic material can include inorganic materials and/or intrinsic organic materials. Examples of inorganic material include, for example, inorganic semiconductors. The inorganic material can be amorphous or polycrystalline. An organic charge transport material can be polymeric or non-polymeric.

Examples of such Inorganic materials and other information related to fabrication of inorganic charge transport layers are discussed further below and in more detail in U.S. Patent Application No. 60/653,094 entitled “Light Emitting Device Including Semiconductor Nanocrystals, filed 16 Feb. 2005, the disclosure of which is hereby incorporated herein by reference in its entirety.

Charge transport layers comprising an inorganic semiconductor can be deposited at a low temperature, for example, by a known method, such as a vacuum vapor deposition method, an ion-plating method, sputtering, inkjet printing, etc.

Charge transport layers comprising intrinsic (undoped) organic materials and other information related to fabrication of intrinsic organic charge transport layers are discussed in more detail in U.S. patent application Ser. Nos. 11/253,612 entitled “Method And System For Transferring A Patterned Material”, filed 21 Oct. 2005, and 11/253,595 entitled “Light Emitting Device Including Semiconductor Nanocrystals”, filed 21 Oct. 2005, each of which is hereby incorporated herein by reference in its entirety.

Charge transport layers including organic materials (doped or undoped) can be disposed by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., <10⁻⁸ torr), high vacuum (e.g., from about 10⁻⁸ torr to about 10⁻⁵ torr), or low vacuum conditions (e.g., from about 10⁻⁵ torr to about 10⁻³ torr). Most preferably, the organic layers are deposited at high vacuum conditions of from about 1×10⁻⁷ to about 5×10⁻⁶ torr. Alternatively, doped organic layers can be formed by multi-layer coating while appropriately selecting solvent for each layer.

The layers can be deposited on a surface of one of the electrodes by spin coating, dip coating, vapor deposition, or other thin film deposition methods. See, for example, M. C. Schlamp, et al., J. Appl. Phys., 82, 5837-5842, (1997); V. Santhanam, et al., Langmuir, 19, 7881-7887, (2003); and X. Lin, et al., J. Phys. Chem. B, 105, 3353-3357, (2001), each of which is incorporated by reference in its entirety.

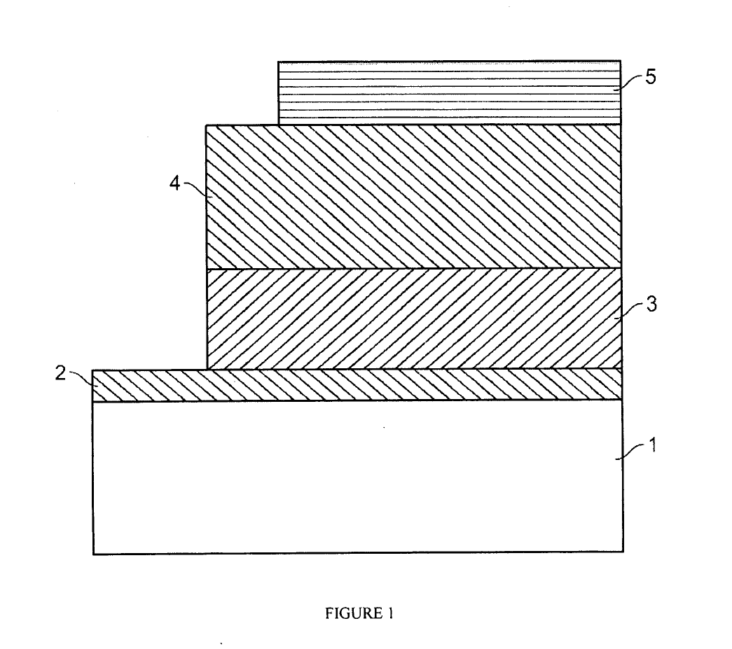

An example of an embodiment of a device including two layers disposed between the two electrodes of the device is shown in FIG. 1. The device structure shown in FIG. 1 is an example of an embodiment of a light-emitting device. The example depicted includes a first electrode 2 disposed over a substrate, a first layer 3 in electrical connection with the electrode 2, a second layer 4 in electrical connection with the first layer 3, and a second electrode 5 in electrical connection with the second layer 4. The first layer 3 can be a hole transport layer and the second layer 4 can be an electron transport layer. At least one layer can be non-polymeric. As discussed above, the semiconductor nanocrystals can be included in the first layer or the second layer. Alternatively, a separate emissive layer including semiconductor nanocrystals (not shown in FIG. 1) can be included between the hole transport layer and the electron transport layer. In a light-emitting device, the semiconductor nanocrystals can be selected based upon their light-emissive characteristics (e.g., the wavelength of the photon emitted, by the nanocrystal when voltage is applied across the device). In the embodiment depicted in FIG. 1 the first electrode of the structure is in contact with the substrate 1. Each electrode can be connected to a power supply to provide a voltage across the structure. Electroluminescence can be produced by the semiconductor nanocrystals of the heterostructure when a voltage of proper polarity is applied across the heterostructure.

In the example shown in FIG. 1, light is emitted from the bottom of the structure (through the ITO coated glass). If an adequately light transmissive top electrode is used, the structure could emit light from the top of the structure.

Alternatively, the structure of FIG. 1 can be inverted, in which case light can be emitted from the top.

The color of the light output of the device can be precisely controlled by the selection of the composition, structure, and size of the various semiconductor nanocrystals included in the device as the emissive material. In certain embodiments, two or more different semiconductor nanocrystals (having different compositions, structures, and/or sizes) can be included.

The first electrode can be, for example, an anode comprising a high work function (e.g., great than 4.0 eV) hole-injecting conductor, such as an indium tin oxide (ITO) layer. Other anode materials include other high work function hole-injection conductors including, but not limited to, for example, tungsten, nickel, cobalt, platinum, palladium and their alloys, gallium indium tin oxide, zinc indium tin oxide, titanium nitride, polyaniline, or other high work function hole-injection conducting polymers. In certain embodiments, the first electrode is light transmissive or transparent. In addition to ITO, examples of other light-transmissive electrode materials include conducting polymers, and other metal oxides, low or high work function metals, or conducting epoxy resins that are at least partially light transmissive. An example of a conducting polymer that can be used as an electrode material is poly(ethlyendioxythiophene), sold by Bayer AG under the trade mark PEDOT. Other molecularly altered poly(thiophenes) are also conducting and could be used, as well as emaraldine salt form of polyaniline.

The second electrode can be, for example, a cathode comprising a low work function (e.g., less than 4.0 eV), electron-injecting, metal, such as Al, Ba, Yb, Ca, a lithium-aluminum alloy (Li:Al), or a magnesium-silver alloy (Mg:Ag). The second electrode, such as Mg:Ag, can optionally be covered with an opaque protective metal layer, for example, a layer of Ag for protecting the cathode layer from atmospheric oxidation, or a relatively thin layer of substantially transparent ITO. The second electrode can be sandwiched, sputtered, or evaporated onto the exposed surface of the solid layer. One or both of the electrodes can be patterned. The electrodes of the device can be connected to a voltage source by electrically conductive pathways. Upon application of the voltage, light is generated from the device.

In a device such as that shown in FIG. 1, for example, the first electrode can have a thickness of about 500 Angstroms to 4000 Angstroms. The first layer can have a thickness of about 50 Angstroms to about 1000 Angstroms. The second layer can have a thickness of about 50 Angstroms to about 1000 Angstroms. The second electrode can have a thickness of about 50 Angstroms to greater than about 1000 Angstroms.

Non-polymeric electrode materials can be deposited by, for example, sputtering or evaporating. Polymeric electrode materials can be deposited by, for example, spin-casting.

As discussed above, the electrodes can be patterned. Electrode material, including light-transmittable electrode material, can be patterned by, for example, a chemical etching method such as a photolithography or a physical etching method using laser, etc. Also, the electrode may be patterned by vacuum vapor deposition, sputtering, etc. while masking.

The substrate can be opaque, light transmissive, or transparent. The substrate can be rigid or flexible. The substrate can be plastic, metal or glass.

In some applications, the substrate can include a backplane. The backplane includes active or passive electronics for controlling or switching power to individual pixels. Including a backplane can be useful for applications such as displays, sensors, or imagers. In particular, the backplane can be configured as an active matrix, passive matrix, fixed format, direct drive, or hybrid. The display can be configured for still images, moving images, or lighting. A display including an array of light emitting devices can provide white light, monochrome light, or color-tunable light.

As discussed above, the device of the invention includes semiconductor nanocrystals. Semiconductor nanocrystals comprise nanometer-scale inorganic semiconductor particles. Semiconductor nanocrystals included in the device of the invention preferably have an average semiconductor nanocrystal diameter less than about 150 Angstroms (\acute{Å}), and most preferably in the range of 12-150 \acute{Å}.

Semiconductor nanocrystals include, for example, inorganic crystallites between about 1 nm and about 1000 nm in diameter, preferably between about 2 nm and about 50 nm, more preferably about 5 nm to about 20 nm (such as about 6, 7, 8, 9, 10, 11, 12, 13, 14, 15, 16, 17, 18, 19, or 20 nm).

The semiconductor forming the semiconductor nanocrystals comprises Group II-VI compounds, Group II-V compounds, Group III-VI compounds, Group III-V compounds, Group IV-VI compounds, Group compounds, Group II-IV-VI compounds, or Group II-IV-V compounds, for example, ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, alloys thereof, and/or mixtures thereof, including ternary and quaternary mixtures.

Examples of the shape of the semiconductor nanocrystals include sphere, rod, disk, other shape or mixtures thereof.

Preferably, the semiconductor nanocrystals include a “core” of one or more first semiconductor materials, and which may be surrounded by an overcoating or “shell” of a second semiconductor material. A semiconductor nanocrystal core surrounded by a semiconductor shell is also referred to as a “core/shell” semiconductor nanocrystal.

For example, the semiconductor nanocrystal can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of materials suitable for use as semiconductor nanocrystal cores include, but are not limited to, CdS, CdSe, CdTe, ZnS, ZnSe, ZnTe, MgTe, GaAs, GaP, GaSb, GaN, HgS, HgSe, HgTe, InAs, InP, InSb, InN, AlAs, AlP, AlSb, AlS, PbS, PbSe, Ge, Si, alloys thereof, and/or mixtures thereof, including ternary and quaternary mixtures.

The shell can be a semiconductor material having a composition that is the same as or different from the composition of the core. The shell comprises an overcoat of a semiconductor material on a surface of the core semiconductor nanocrystal can include a Group II-VI compounds, Group II-V compounds, Group III-VI compounds, Group III-V compounds, Group IV-VI compounds, Group compounds, Group II-IV-VI compounds, and Group II-IV-V compounds, for example, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, alloys thereof, and/or mixtures thereof, including ternary and quaternary mixtures. For example, ZnS, ZnSe or CdS overcoatings can be grown on CdSe or CdTe semiconductor nanocrystals. An overcoating process is described, for example, in U.S. Pat. No. 6,322,901. By adjusting the temperature of the reaction mixture during overcoating and monitoring the absorption spectrum of the core, over coated materials having high emission quantum efficiencies and narrow size distributions can be obtained. The overcoating may comprise one or more layers. The overcoating comprises at least one semiconductor material which is the same as or different from the composition of the core. Preferably, the overcoating has a thickness of from about one to about ten monolayers.

In one embodiment, the surrounding “shell” material can have a band gap greater than the band gap of the core material and can be chosen so as to have an atomic spacing close to that of the “core” substrate. In another embodiment, the surrounding shell material can have a band gap less than the band gap of the core material. In a further embodiment, the shell and core materials can have the same crystal structure.

Examples of semiconductor nanocrystal (core)shell materials include, without limitation: red (e.g., (CdSe)ZnS (core)shell), green (e.g., (CdZnSe)CdZnS (core)shell, etc.), and blue (e.g., (CdS)CdZnS (core)shell.

For further examples of core/shell semiconductor structures, see U.S. application Ser. No. 10/638,546, entitled “Semiconductor Nanocrystal Heterostructures”, filed 12 Aug. 2003, which is hereby incorporated herein by reference in its entirety.

Preparation and manipulation of semiconductor nanocrystals are described, for example, in U.S. Pat. Nos. 6,322,901 and 6,576,291, and U.S. Patent Application No. 60/550,314, each of which is hereby incorporated herein by reference in its entirety. One method of manufacturing a semiconductor nanocrystal is a colloidal growth process. Colloidal growth occurs by injection an M donor and an X donor into a hot coordinating solvent. One example of a preferred method for preparing monodisperse semiconductor nanocrystals comprises pyrolysis of organometallic reagents, such as dimethyl cadmium, injected into a hot, coordinating solvent. This permits discrete nucleation and results in the controlled growth of macroscopic quantities of semiconductor nanocrystals. The injection produces a nucleus that can be grown in a controlled manner to form a semiconductor nanocrystal. The reaction mixture can be gently heated to grow and anneal the semiconductor nanocrystal. Both the average size and the size distribution of the semiconductor nanocrystals in a sample are dependent on the growth temperature. The growth temperature necessary to maintain steady growth increases with increasing average crystal size. The semiconductor nanocrystal is a member of a population of semiconductor nanocrystals. As a result of the discrete nucleation and controlled growth, the population of semiconductor nanocrystals obtained has a narrow, monodisperse distribution of diameters. The monodisperse distribution of diameters can also be referred to as a size. Preferably, a monodisperse population of particles includes a population of particles wherein at least 60% of the particles in the population fall within a specified particle size range. A population of monodisperse particles preferably deviate less than 15% rms (root-mean-square) in diameter and more preferably less than 10% rms and most preferably less than 5%.

The narrow size distribution of the semiconductor nanocrystals allows the possibility of light emission in narrow spectral widths. Monodisperse semiconductor nanocrystals have been described in detail in Murray et al. (J. Am. Chem. Soc., 115:8706 (1993)); in the thesis of Christopher Murray, “Synthesis and Characterization of II-VI Quantum Dots and Their Assembly into 3-D Quantum Dot Superlattices”, Massachusetts Institute of Technology, September, 1995; and in U.S. patent application Ser. No. 08/969,302 entitled “Highly Luminescent Color-selective Materials” which are hereby incorporated herein by reference in their entireties.

The process of controlled growth and annealing of the semiconductor nanocrystals in the coordinating solvent that follows nucleation can also result in uniform surface derivatization and regular core structures. As the size distribution sharpens, the temperature can be raised to maintain steady growth. By adding more M donor or X donor, the growth period can be shortened. The M donor can be an inorganic compound, an organometallic compound, or elemental metal. M is cadmium, zinc, magnesium, mercury, aluminum, gallium, indium or thallium. The X donor is a compound capable of reacting with the M donor to form a material with the general formula MX. The X donor can be a chalcogenide donor or a pnictide donor, such as a phosphine chalcogenide, a bis(silyl) chalcogenide, dioxygen, an ammonium salt, or a tris(silyl) pnictide. Suitable X donors include dioxygen, bis(trimethylsilyl) selenide ((TMS)₂Se), trialkyl phosphine selenides such as (tri-noctylphosphine) selenide (TOPSe) or (tri-n-butylphosphine)selenide (TBPSe), trialkyl phosphine tellurides such as (tri-n-octylphosphine)telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-noctylphosphine)sulfide (TOPS), an ammonium salt such as an ammonium halide (e.g., NH4Cl), tris(trimethylsilyl)phosphide ((TMS)₃P), tris(trimethylsilyl)arsenide ((TMS)₃As), or tris(trimethylsilyl)antimonide ((TMS)₃Sb). In certain embodiments, the M donor and the X donor can be moieties within the same molecule.

A coordinating solvent can help control the growth of the semiconductor nanocrystal. The coordinating solvent is a compound having a donor lone pair that, for example, has a lone electron pair available to coordinate to a surface of the growing semiconductor nanocrystal. Solvent coordination can stabilize the growing semiconductor nanocrystal. Examples of coordinating solvents include alkyl phosphines, alkyl phosphine oxides, alkyl phosphonic acids, or alkyl phosphinic acids, however, other coordinating solvents, such as pyridines, furans, and amines may also be suitable for the semiconductor nanocrystal production. Examples of suitable coordinating solvents include pyridine, tri-n-octyl phosphine (TOP), tri-n-octyl phosphine oxide (TOPO) and trishydroxylpropylphosphine (tHPP). Technical grade TOPO can be used.

Size distribution during the growth stage of the reaction can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystals. For example, for CdSe and CdTe, by stopping growth at a particular semiconductor nanocrystal average diameter and choosing the proper composition of the semiconducting material, the emission spectra of the semiconductor nanocrystals can be tuned continuously over the wavelength range of 300 nm to 5 microns, or from 400 nm to 800 nm.

The particle size distribution of the semiconductor nanocrystals can be further refined by size selective precipitation with a poor solvent for the semiconductor nanocrystals, such as methanol/butanol as described in U.S. Pat. No. 6,322,901. For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected semiconductor nanocrystal population preferably has no more than a 15% rms deviation from mean diameter, more preferably 10% rms deviation or less, and most preferably 5% rms deviation or less.

As discussed herein, the semiconductor nanocrystals preferably have ligands attached thereto.

In one embodiment, the ligands are derived from the coordinating solvent used during the growth process. The surface can be modified by repeated exposure to an excess of a competing coordinating group to form an overlayer. For example, a dispersion of the capped semiconductor nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the semiconductor nanocrystal, including, for example, phosphines, thiols, amines and phosphates. The semiconductor nanocrystal can be exposed to short chain polymers which exhibit an affinity for the surface and which terminate in a moiety having an affinity for a suspension or dispersion medium. Such affinity improves the stability of the suspension and discourages flocculation of the semiconductor nanocrystal.

The organic ligands can be useful in facilitating large area, non-epitaxial deposition of highly stable inorganic nanocrystals within a device.

More specifically, the coordinating ligand can have the formula:

(Y—)ₖ₋ₙ—(X)-L)ₙ

wherein k is 2, 3 or 5, and n is 1, 2, 3, 4 or 5 such that k−n is not less than zero; X is O, S, S═O, SO2, Se, Se═O, N, N═O, P, P═O, As, or As═O; each of Y and L, independently, is aryl, heteroaryl, or a straight or branched C2-12 hydrocarbon chain optionally containing at least one double bond, at least one triple bond, or at least one double bond and one triple bond. The hydrocarbon chain can be optionally substituted with one or more C1-4 alkyl, C2-4 alkenyl, C2-4 alkynyl, C1-4 alkoxy, hydroxyl, halo, amino, nitro, cyano, C3-5 cycloalkyl, 3-5 membered heterocycloalkyl, aryl, heteroaryl, C1-4 alkylcarbonyloxy, C1-4 alkyloxycarbonyl, C1-4 alkylcarbonyl, or formyl. The hydrocarbon chain can also be optionally interrupted by —O—, —S—, —N(Ra)—, —N(Ra)—C(O)—O—, —O—C(O)—N(Ra)—, —N(Ra)—C(O)—N(Rb)—, —O—C(O)—O—, —P(Ra)—, or —P(O)(Ra)—. Each of Ra and Rb, independently, is hydrogen, alkyl, alkenyl, alkynyl, alkoxy, hydroxylalkyl, hydroxyl, or haloalkyl. An aryl group is a substituted or unsubstituted cyclic aromatic group. Examples include phenyl, benzyl, naphthyl, tolyl, anthracyl, nitrophenyl, or halophenyl. A heteroaryl group is an aryl group with one or more heteroatoms in the ring, for instance furyl, pyridyl, pyrrolyl, phenanthryl.

A suitable coordinating ligand can be purchased commercially or prepared by ordinary synthetic organic techniques, for example, as described in J. March, Advanced Organic Chemistry, which is hereby incorporated by reference in its entirety.

See also U.S. patent application Ser. No. 10/641,292 entitled “Stabilized Semiconductor Nanocrystals”, filed 15 Aug. 2003, which is hereby incorporated herein by reference in its entirety.

When the electron and hole localize on a semiconductor nanocrystal, emission can occur at an emission wavelength. The emission has a frequency that corresponds to the band gap of the quantum confined semiconductor material. The band gap is a function of the size of the semiconductor nanocrystal. Semiconductor nanocrystals having small diameters can have properties intermediate between molecular and bulk forms of matter. For example, semiconductor nanocrystals based on semiconductor materials having small diameters can exhibit quantum confinement of both the electron and hole in all three dimensions, which leads to an increase in the effective band gap of the material with decreasing crystallite size. Consequently, both the optical absorption and emission of semiconductor nanocrystals shift to the blue, or to higher energies, as the size of the crystallites decreases.

The emission from the semiconductor nanocrystal can be a narrow Gaussian emission band that can be tuned through the complete wavelength range of the ultraviolet, visible, or infra-red regions of the spectrum by varying the size of the semiconductor nanocrystal, the composition of the semiconductor nanocrystal, or both. For example, CdSe can be tuned in the visible region and InAs can be tuned in the infra-red region. The narrow size distribution of a population of semiconductor nanocrystals can result in emission of light in a narrow spectral range. The population can be monodisperse preferably exhibits less than a 15% rms (root-mean-square) deviation in diameter of the semiconductor nanocrystals, more preferably less than 10%, most preferably less than 5%. Spectral emissions in a narrow range of no greater than about 75 nm, preferably 60 nm, more preferably 40 nm, and most preferably 30 nm full width at half max (FWHM) for semiconductor nanocrystals that emit in the visible can be observed. IR-emitting semiconductor nanocrystals can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of semiconductor nanocrystal diameters decreases. Semiconductor nanocrystals can have high emission quantum efficiencies such as greater than 10%, 20%, 30%, 40%, 50%, 60%, 70%, or 80%.

The narrow FWHM of semiconductor nanocrystals can result in saturated color emission. This can lead to efficient lighting devices even in the red and blue parts of the visible spectrum, since in semiconductor nanocrystal emitting devices no photons are lost to infra-red and UV emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of semiconductor nanocrystals will emit light spanning a narrow range of wavelengths. A device including more than one size of semiconductor nanocrystal can emit light in more than one narrow range of wavelengths. The color of emitted light perceived by a viewer can be controlled by selecting appropriate combinations of semiconductor nanocrystal sizes and materials in the device as well as relative subpixel currents. The degeneracy of the band edge energy levels of semiconductor nanocrystals facilitates capture and radiative recombination of all possible excitons, whether generated by direct charge injection or energy transfer. The maximum theoretical semiconductor nanocrystal lighting device efficiencies are therefore comparable to the unity efficiency of phosphorescent organic light-emitting devices. The excited state lifetime (τ) of the semiconductor nanocrystal is much shorter (τ˜10 ns) than a typical phosphor (τ>0.1 μs), enabling semiconductor nanocrystal lighting devices to operate efficiently even at high current density and high brightness.

Transmission electron microscopy (TEM) can provide information about the size, shape, and distribution of the semiconductor nanocrystal population. Powder X-ray diffraction (XRD) patterns can provide the most complete information regarding the type and quality of the crystal structure of the semiconductor nanocrystals. Estimates of size are also possible since particle diameter is inversely related, via the X-ray coherence length, to the peak width. For example, the diameter of the semiconductor nanocrystal can be measured directly by transmission electron microscopy or estimated from X-ray diffraction data using, for example, the Scherrer equation. It also can be estimated from the UV/V is absorption spectrum.

As discussed above, the semiconductor nanocrystals can be included in the hole transport layer. Alternatively, the semiconductor nanocrystals can be included in the electron transport layer. When included in a hole transport layer and/or in an electron transport layer, for example the semiconductor nanocrystals can be included in the material of the layer. Alternatively, the semiconductor nanocrystals can be included as one or more separate layers between two hole transport layers and/or between two electron transport layers. In either case, each of the charge transport layers may further comprise one or more layers. In another embodiment, the semiconductor nanocrystals can be disposed as one or more separate emissive layers disposed between a hole transport layer and an electron transport layer. Alternatively, the semiconductor nanocrystals can be disposed between any two other layers of the device. As discussed above, other layers may also be included between the electron transport layers and the hole transport layers. When included in the device as a separate layer, for example, the semiconductor nanocrystals can be disposed as a continuous or substantially continuous thin film or layer. When disposed as a separate layer, the layer can be patterned or unpatterned. Preferably, the semiconductor nanocrystals included in the device comprise a substantially monodisperse population of semiconductor nanocrystals.

In certain embodiments, semiconductor nanocrystals are included in a device at a monolayer thickness. In a light-emitting device, a monolayer can provide the beneficial light emission properties of semiconductor nanocrystals while minimizing the impact on electrical performance. However, thicker layers including semiconductor nanocrystals can alternatively be included.

In certain embodiments, the semiconductor nanocrystals are deposited at a thickness of multiple monolayers or less. For example, the thickness can be greater than three monolayers, three or less monolayers, two or less monolayers, a single monolayer, a partial monolayer, etc. The thickness of each deposited layer of semiconductor nanocrystals may vary. Preferably, the variation of the thickness at any point of the deposited semiconductor nanocrystals is less than three monolayers, more preferably less than two monolayers, and most preferably less than one monolayer. When deposited as a single monolayer, preferably at least about 60% of the semiconductor nanocrystals are at single monolayer thickness, more preferably, at least about 80% of the semiconductor nanocrystals are at single monolayer thickness, and most preferably, at least about 90% of the semiconductor nanocrystals are at single monolayer thickness. As discussed herein, the semiconductor nanocrystals can optionally be deposited as in a patterned or unpatterned arrangement.

Semiconductor nanocrystals show strong quantum confinement effects that can be harnessed in designing bottom-up chemical approaches to create complex heterostructures with electronic and optical properties that are tunable with the size and composition of the semiconductor nanocrystals.

Light-emitting devices including semiconductor nanocrystals can be made by spin-casting a solution containing the HTL organic semiconductor molecules and the semiconductor nanocrystals, where the HTL forms underneath the semiconductor nanocrystal layer via phase separation (see, for example, U.S. patent application Ser. Nos. 10/400,907 and 10/400,908, both filed Mar. 28, 2003, each of which is incorporated by reference in its entirety). In certain embodiments, this phase separation technique can be used to place a monolayer of semiconductor nanocrystals between an organic semiconductor HTL and ETL, thereby effectively exploiting the favorable light emission properties of semiconductor nanocrystals, while minimizing their impact on electrical performance. Other techniques for depositing semiconductor nanocrystals include Langmuir-Blodgett techniques and drop-casting. Some techniques for depositing semiconductor nanocrystals may not be well suited for all possible substrate materials, may involve use of chemicals that can affect the electrical or optical properties of the layer, may subject the substrate to harsh conditions, and/or may place constraints on the types of devices that can be grown in some way. Other techniques discussed below may be preferable if a patterned layer of semiconductor nanocrystals is desired.

Preferably, semiconductor nanocrystals are processed in a controlled (oxygen-free and moisture-free) environment, preventing the quenching of luminescent efficiency during the fabrication process.

In certain embodiments, the semiconductor nanocrystals can be deposited in a patterned arrangement. Patterned semiconductor nanocrystals can be used to form an array of pixels comprising, e.g., red, green, and blue or alternatively, red, yellow, green, blue-green, and/or blue emitting, or other combinations of distinguishable color emitting subpixels, that are energized to produce light of a predetermined wavelength.

A preferred technique for depositing a light-emitting material comprising semiconductor nanocrystals in a pattern and/or in a multi-color pattern or other array is contact printing. Contact printing advantageously allows micron-scale (e.g., less than 1 mm, less than 500 microns, less than 200 microns, less than 100 microns, less than 50 microns, less than 25 microns, or less than 10 microns) patterning of features on a surface. Pattern features can also be applied at larger scales, such as 1 mm or greater, 1 cm or greater, 1 m of greater, 10 m or greater. Contact printing can allow dry (e.g., liquid free or substantially liquid free) application of a patterned semiconductor nanocrystal layer to a surface. In a pixilated device, the semiconductor nanocrystal layer comprises a patterned array of the semiconductor nanocrystals on the underlying layer. In instances where a pixel includes subpixels, the sizes of the subpixels can be a proportionate fraction of the pixel size, based on the number of subpixels.

Additional information and methods for depositing semiconductor nanocrystals are described in U.S. patent application Ser. Nos. 11/253,612 entitled “Method And System For Transferring A Patterned Material”, filed 21 Oct. 2005, and 11/253,595 entitled “Light Emitting Device Including Semiconductor Nanocrystals”, filed 21 Oct. 2005, each of which is hereby incorporated herein by reference in its entirety.

Other techniques, methods and applications that may be useful with the present invention are described in, U.S. Provisional Patent Application (Attorney Docket No. QDV001), of Seth Coe-Sullivan, Et al., for “Composition Including Material, Methods Of Depositing Material, Articles Including Same And Systems For Depositing Material”, filed by Express Mail on 14 Apr. 2006; U.S. Provisional Patent Application (Attorney Docket No. QDV002), of Maria J. Anc, For “Methods Of Depositing Material, Methods Of Making A Device, And System”, filed by Express Mail in 14 Apr. 2006, U.S. Provisional Patent Application (Attorney Docket No. QDV021), of Marshall Cox, et al, for “Methods Of Depositing Nanomaterial & Methods Of Making A Device” filed by Express Mail on 14 Apr. 2006; U.S. Provisional Patent Application (Attorney Docket No. QDV022) of Seth Coe-Sullivan, et al, for “Articles For Depositing Materials, Transfer Surfaces, And Methods” filed by Express Mail on 14 Apr. 2006, U.S. Provisional Patent Application (Attorney Docket No. QDV026) of LeeAnn Kim et al., for “Applicator For Depositing Materials And Methods” filed by Express Mail on 14 Apr. 2006; U.S. Provisional Patent Application (Attorney Docket No. QDV026P2) of LeeAnn Kim et al., for “Applicator For Depositing Materials And Methods” filed by Express Mail on 21 Apr. 2006; and U.S. Provisional Patent Application No. 60/790,393 of Seth Coe-Sullivan et al., for “Methods And Articles Including Nanomaterial”, filed on 7 Apr. 2006. The disclosures of each of the foregoing listed provisional patent applications are hereby incorporated herein by reference in their entireties.

Other multilayer structures may optionally be used to improve the performance (see, for example, U.S. patent application Ser. Nos. 10/400,907 and 10/400,908, filed Mar. 28, 2003, each of which is incorporated herein by reference in its entirety) of the light-emitting devices and displays of the invention.

The performance of light emitting devices can be improved by increasing their efficiency, narrowing or broadening their emission spectra, or polarizing their emission. See, for example, Bulovic et al., Semiconductors and Semimetals 64, 255 (2000), Adachi et al., Appl. Phys. Lett. 78, 1622 (2001), Yamasaki et al., Appl. Phys. Lett. 76, 1243 (2000), Dirr et al., Jpn. J. Appl. Phys. 37, 1457 (1998), and D'Andrade et al., MRS Fall Meeting, BB6.2 (2001), each of which is incorporated herein by reference in its entirety. Semiconductor nanocrystals can be included in efficient hybrid organic/inorganic light emitting devices.

Because of the diversity of semiconductor nanocrystal materials that can be prepared, and the wavelength tuning via semiconductor nanocrystal composition, structure, and size, devices that can emit light of a predetermined color are possible with use of semiconductor nanocrystals as the emissive material. Semiconductor nanocrystal light-emitted devices can be tuned to emit anywhere in the spectrum.

Light-emitting devices can be prepared that emit visible or invisible (e.g., IR) light. The size and material of a semiconductor nanocrystal can be selected such that the semiconductor nanocrystal emits light having a predetermined wavelength. Light emission can be of a predetermined wavelength in any region of the spectrum, e.g., visible, infrared, etc. For example, the wavelength can be between 300 and 2,500 nm or greater, for instance between 300 and 400 nm, between 400 and 700 nm, between 700 and 1100 nm, between 1100 and 2500 nm, or greater than 2500 nm.

Individual light-emitting devices can be formed. In other embodiments, a plurality of individual light-emitting devices can be formed at multiple locations on a single substrate to form a display. The display can include devices that emit at the same or different wavelengths. By patterning the substrate with arrays of different color-emitting semiconductor nanocrystals, a display including pixels of different colors can be formed.

An individual light-emitting device or one or more light-emitting devices of a display can optionally include a mixture of different color-emitting semiconductor nanocrystals formulated to produce a white light. White light can alternatively be produced from a device including red, green, blue, and, optionally, additional pixels.

Examples of other displays are included in U.S. Patent Application No. 60/771,643 for “Displays Including Semiconductor Nanocrystals And Methods Of Making Same”, of Seth Coe-Sullivan et al., filed 9 Feb. 2006, the disclosure of which is hereby incorporated herein by reference in its entirety.

In another embodiment of the invention, the device can be a photodetector. In a photodetector, semiconductor nanocrystals are engineered to produce a predetermined electrical response upon absorption of a particular wavelength, e.g., in the IR, MIR, or other region of the spectrum. Examples of photodetector devices including semiconductor nanocrystals are described in “A Quantum Dot Heterojunction Photodetector” by Alexi Cosmos Arango, Submitted to the Department of Electrical Engineering and Computer Science, in partial fulfillment of the requirements for the degree of Masters of Science in Computer Science and Engineering at the Massachusetts Institute of Technology, February 2005, the disclosure of which is hereby incorporated herein by reference in its entirety. A photodetector further includes a hole transport layer and/or an electron transport layer. In accordance with the invention, a doped organic material can be included in a layer of a photodetector. In certain embodiments, one or both of the charge transport layers of a photodetector device can include a doped organic material. Optionally, one or more additional layers comprising doped organic material can be included in the photodetector device. One or more photodetectors including semiconductor nanocrystals and a layer comprising a doped organic material can further be included in an imaging device, such as an hyperspectral imaging device. See, for example, U.S. Provisional Application No. 60/785,786 of Coe-Sullivan et al. for “Hyperspectral Imaging Device”, filed 24 Mar. 2006, the disclosure of which is hereby incorporated herein by reference in its entirety.

For additional information relating to semiconductor nanocrystals and their use, see also U.S. Patent Application Nos. 60/620,967, filed Oct. 22, 2004, and 11/032,163, filed Jan. 11, 2005, U.S. patent application Ser. No. 11/071,244, filed 4 Mar. 2005. Each of the foregoing patent applications is hereby incorporated herein by reference in its entirety.

All the patents and publications mentioned above and throughout are incorporated in their entirety by reference herein.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A device comprising: semiconductor nanocrystals and a layer comprising a doped organic material.

2. A device in accordance with claim 1 wherein the doped organic material comprises a material that can transport electrons.

3. A device in accordance with claim 2 wherein the doped organic material is n-doped.

4. (canceled)

5. A device in accordance with claim 1 wherein the doped organic material comprises a material that can transport holes.

6. (canceled)

7. (canceled)

8. A device in accordance with claim 5 wherein the doped organic material is p-doped.

9. A device in accordance with claim 1 wherein the doped organic material comprises a material that can inject holes.

10. A device in accordance with claim 9 wherein the doped organic material is p-doped.

11. (canceled)

12. A device in accordance with claim 1 wherein the doped organic material comprises a material that can inject electrons.

13. A device in accordance with claim 12 wherein the doped organic material is n-doped.

14. (canceled)

15. A device in accordance with claim 1 wherein the doped organic material comprises a material that can block holes.

16. A device in accordance with claim 1 wherein the doped organic material comprises a material that blocks electrons.

17. A device in accordance with claim 1 wherein the device comprises more than one layer comprising a doped organic material is included in the device.

18. (canceled)

19. (canceled)

20. (canceled)

21. (canceled)

22. (canceled)

23. (canceled)

24. (canceled)

25. (canceled)

26. A method for improving the efficiency of a device including semiconductor nanocrystals comprising including a layer comprising a doped organic material in electrical connection with at least one semiconductor nanocrystal.

27. A method in accordance with claim 26 wherein the doped organic material comprises a material that can transport electrons.

28. A method in accordance with claim 26 wherein the doped organic material comprises a material that can transport holes.

29. A method in accordance with claim 26 wherein the doped organic material comprises a material that can inject holes.

30. A method in accordance with claim 26 wherein the doped organic material comprises a material that can inject electrons.

31. A method in accordance with claim 26 wherein the doped organic material comprises a material that can block holes.

32. A method in accordance with claim 26 wherein the doped organic material comprises a material that blocks electrons.

33. A method in accordance with claim 26 further comprising providing one or more additional layers comprising a doped organic material is included in the device.

34. A method for improving the efficiency of a device including: providing a substrate including an electrode, depositing a first layer comprising a first doped organic material over the substrate and in electrical connection with at least one semiconductor nanocrystal.

35. A method in accordance with claim 34 wherein the semiconductor nanocrystals are included in the first layer.

36. (canceled)

37. A method in accordance with claim 34 further comprising depositing a second layer comprising a second doped organic material over the first layer.

38. A method in accordance with claim 34 wherein the first doped organic material comprises a material capable of transporting holes and the second doped organic material comprises a material capable of transporting electrons.

39. A method in accordance with claim 34 wherein the semiconductor nanocrystals are included in the second layer.

40. A method in accordance with claim 37 wherein the semiconductor nanocrystals are disposed as a separate layer between the first layer and second layer.

41. (canceled)

43. (canceled)

44. A device in accordance with claim 1 wherein the semiconductor nanocrystals comprise a core/shell structure.

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. A method in accordance with claim 26 wherein the semiconductor nanocrystals comprise a core/shell structure.

59. (canceled)

60. (canceled)

61. (canceled)

62. (canceled)

63. (canceled)

64. (canceled)

65. A method in accordance with claim 34 wherein the semiconductor nanocrystals comprise a core/shell structure.

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)

79. (canceled)

80. (canceled)

81. (canceled)

82. A method in accordance with claim 27 wherein the doped organic material is n-doped.

83. (canceled)

84. (canceled)

85. (canceled)

86. A method in accordance with claim 28 wherein the doped organic material is p-doped.

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. A device in accordance with claim 1 wherein the device comprises a light-emitting device.

105. A device in accordance with claim 1 wherein the device comprises a solar cell.

106. A device in accordance with claim 1 wherein the device comprises a photodetector.

107. A device in accordance with claim 1 wherein the device comprises a photovoltaic device.

108. An imaging device comprising a plurality of photodetectors in accordance with claim 106.

109. A display comprising a plurality of light-emitting devices in accordance with claim 104.

110. (canceled)

111. (canceled)

112. (canceled)
